(19) United States
(12) Patent Application Publication
(10) Pub. No.: US 2011/0024865 A1
(43) Pub. Date: Feb. 3, 2011

(54) SEMICONDUCTOR LIGHT RECEIVING DEVICE

(75) Inventors: Takashi MATSUMOTO, Kanagawa (JP); Isao WATANABE, Kanagawa (JP); Tomoaki KOI, Kanagawa (JP)

Correspondence Address: YOUNG & THOMPSON, 209 Madison Street, Suite 500, Alexandria, VA, 22314, US

(73) Assignee: NEC ELectronics Corporation, Kanagawa (JP)

(21) Appl. No.: 12/825,946

(22) Filed: Jun. 29, 2010

(30) Foreign Application Priority Data
Jul. 30, 2009 (JP) 2009-177289

(51) Int. Cl. H01L 31/105

(52) U.S. Cl. 257/458; 257/E31.061

(57) ABSTRACT

According to an exemplary aspect of the present invention, at least a semiconductor mesa and a semiconductor layer covering at least the side wall of the mesa and a semiconductor mesa are formed on an n-type semiconductor substrate. The semiconductor mesa includes at least a light absorption layer and a p-type contact layer. The principal surface of the semiconductor substrate tilts at an angle θ to the (100) plane. The angle θ is 0.1 degree≦|θ|≦10 degrees.

### INCORPORATION BY REFERENCE

This application is based upon and claims the benefit of priority from Japanese patent application No. 2009-177289, filed on Jul. 30, 2009, the disclosure of which is incorporated herein in its entirety by reference.

### BACKGROUND

1. Field of the Invention

The present invention relates to a semiconductor light receiving device, and in particular to a mesa-shaped semiconductor light receiving device.

2. Description of Related Art

In an optical communication system in an access network and a data communication system, semiconductor light receiving devices, like PIN-PD (p-intrinsic-n photodiode) and APD (avalanche photodiode) that have gigabit responsiveness, are used. These semiconductor light receiving devices are required to have a simple structure, excellent mass productivity and reliability, and low producing cost.

Examples of the semiconductor light receiving device having the characteristics described above are disclosed in Japanese Unexamined Patent Application Publication Nos. 2008-66329, 2004-119563, 10-112551, and 64-22072. FIG. 8 is a cross sectional view showing a structure of a mesa-shaped PIN-PD 80 disclosed in Japanese Unexamined Patent Application Publication No. 2008-66329. In the mesa-shaped PIN-PD 80, a III-V compound semiconductor layer 82 is grown on a semiconductor substrate 81 made of semi-insulating InP, for example. A III-V compound semiconductor layer 83 having a mesa shape, which is a light absorption layer, is formed on the III-V compound semiconductor layer 82. A III-V compound semiconductor layer 84 is formed on the III-V compound semiconductor layer 83. Herein, the III-V compound semiconductor layers 82 to 84 are made of InGaAs, for example.

Further, an InP semiconductor 85 covering side walls of the III-V compound semiconductor layers 82 to 84 is formed as a passivation layer. Further, a dielectric material layer 86 covering the mesa-shaped PIN-PD 80 is formed. An opening is formed in the InP semiconductor 85 and the dielectric material layer 86 on the III-V compound semiconductor layer 84. A first electrode 87 and an anti-reflection layer 89 are formed in contact with the III-V compound semiconductor layers 84 through the opening. Further, an opening is formed in an area of the dielectric material layer 86 which is formed on the III-V compound semiconductor layer 82 and in which a mesa is not formed. A second electrode 88 is formed in contact with the III-V compound semiconductor layer 82 through the opening.

That is to say, the side walls of the III-V compound semiconductor layer 83, which is the light absorption layer, are covered with the InP semiconductor 85. Therefore, the III-V compound semiconductor layer 83 made of InGaAs having a narrow band gap and the dielectric material layer 86 are not in contact with each other. Thus, the interface between InGaAs and the dielectric material, which causes a dark current to increase due to insufficient time stability, does not exist. In sum, the interface between InP and InGaAs having the sufficient time stability and a wide band gap is formed. Therefore, it is possible to ensure the long-term reliability of the mesa-shaped PIN-PD 80.

An example of a mesa-shaped APD is disclosed in Japanese Unexamined Patent Application Publication No. 2004-119563. In this mesa-shaped APD, the side walls of the light absorption layer made of InGaAs are buried with regrown InP, for example (FIG. 8 of Japanese Unexamined Patent Application Publication No. 2004-119563). Thus, it is possible to obtain the same effect as that of Japanese Unexamined Patent Application Publication No. 2008-66329.

An example of a mesa light waveguide type PIN-PD is disclosed in Japanese Unexamined Patent Application Publication No. 10-112551. In this mesa light waveguide type PIN-PD, a mesa composed of a semiconductor layer including the light absorption layer is formed. The side wall of the mesa is covered with a dielectric material layer. The mesa is formed into a certain shape, thereby making it possible to obtain the effect of reducing a leak current at the interface between the side wall of the mesa and the dielectric material layer.

An example of a planar type PIN-PD is disclosed in Japanese Unexamined Patent Application Publication No. 64-22072. In this plainer type PIN-PD, the principal surface of the semiconductor substrate tilts at a predetermined angle with respect to the (100) plane. Thus, it is possible to uniform the thickness of the semiconductor layer grown on the semiconductor substrate.

The (100) plane described above represents the plane direction of the crystal by Miller indices. Hereinafter, planes and directions in crystal lattice are represented by using Miller indices.

### SUMMARY

The present inventors have found a problem described below. In semiconductor light receiving devices disclosed in Japanese Unexamined Patent Application Publication Nos. 2008-66329 and 2004-119563, a crystal growth method is used as a method of covering the side wall of the mesa with the semiconductor. However, anisotropy of crystal growth depending on the mesa shape is caused by the crystal growth method. Further, coverage of the side wall of the mesa becomes insufficient due to this anisotropy.

In particular, as disclosed in Japanese Unexamined Patent Application Publication No. 2008-66329, the InP substrate having the (100) plane as the principal surface is generally used for manufacturing the light receiving device. A circular mesa is formed on the InP substrate by wet etching, and the circular mesa has an anisotropic shape. Generally, the side wall of the mesa along the <011> direction has a relatively smooth shape. On the other hand, the side wall of the mesa along the <01-1> direction is more likely to have a steep shape.

Further, the growth rate for glowing the semiconductor layer on the mesa in the <011> direction is higher than that for the (100) plane. Therefore, the side wall of the mesa formed along the <011> direction is covered sufficiently. On the other hand, the (111B) plane is newly formed in the side wall of the mesa along the <01-1> direction. Thus, the side wall of the mesa along the <01-1> direction is covered insufficiently due to the occurrence of disconnections, for example, with the result that the light absorption layer is prone to be exposed. FIG. 9 is a cross sectional view showing the side wall of the mesa buried with InP semiconductor in the manufacturing process of the mesa-shaped PIN-PD 80 according to Japanese Unexamined Patent Application Publication No. 2008-66329. As shown in FIG. 9, the disconnection occurs partly in the InP semiconductor 85 covering the side wall of the mesa, and the III-V compound semiconductor layer 83, which is the light absorption layer formed into a mesa shape, is exposed. Hence, the surface leak current increases in the long term. Thus, it is a major problem that the yield ratio for guaranteeing reliability is insufficient.

Japanese Unexamined Patent Application Publication No. 2008-66329 discloses a thermal treatment after the crystal growth as a method for improving the coverage of the side wall of the mesa. However, the addition of the thermal treatment process increases cost. Further, the crystal quality of the semiconductor may be degraded by the thermal treatment process. Furthermore, Japanese Unexamined Patent Application Publication No. 2004-119563 fails to describe a method for improving the coverage of the side wall of the mesa.

A semiconductor light receiving device disclosed in Japanese Unexamined Patent Application Publication No. 10-112551 has a problem in that it is substantially quite difficult to suppress the surface leak current generated at an interface between the light absorption layer and the dielectric material layer at a low dark current level in nA order, and to guarantee the long-term reliability from a viewpoint of repeatability.

Further, a semiconductor light receiving device disclosed in Japanese Unexamined Patent Application Publication No. 64-22072 is a planar type PIN-PD. Therefore, the planar type PIN-PD cannot contribute to the improvement in coverage of the side wall of the mesa.

In sum, according to the techniques disclosed in Japanese Unexamined Patent Application Publication No. 2008-66329, 2004-119563, 10-112551, and 64-22072, it is impossible to cover the side wall of the mesa with reliability in the mesa-shaped semiconductor light receiving device. Therefore, it is impossible to materialize the mesa-shaped semiconductor light receiving device having gigabit responsiveness, low manufacturing cost, and excellent reliability.

A first exemplary aspect of the present invention is a semiconductor light receiving device including a semiconductor substrate having a first conductivity type, a semiconductor mesa arranged over the semiconductor substrate, and a first semiconductor layer covering at least a side wall of the semiconductor mesa, in which the semiconductor mesa includes a light absorption layer and a second semiconductor layer that is arranged over the light absorption layer and has a second conductivity type opposite to the first conductivity type. The principal surface of the semiconductor substrate tilts at an angle θ to a (100) plane by using [01-1] direction as an axis and the angle θ is 0.1 degree≦|θ|≦10 degrees.

According to the semiconductor light receiving device in accordance with an exemplary aspect of the present invention, it is possible to reliably cover the side wall of the mesa along the [01-1] direction with the semiconductor layer. Therefore, it is possible to suppress an increasing in the dark current and a decrease in the breakdown voltage.

According to the present invention, it is possible to provide the semiconductor light receiving device that has the excellent reliability and productivity.

### BRIEF DESCRIPTION OF THE DRAWINGS

The above and other exemplary aspects, advantages and features will be more apparent from the following description of certain exemplary embodiments taken in conjunction with the accompanying drawings, in which:

FIG. 1 is a cross sectional view showing a structure of a semiconductor light receiving device 100 according to a first exemplary embodiment of the present invention;

FIG. 2 is a top view of the semiconductor light receiving device 100;

FIG. 3A is a cross sectional view showing a manufacturing process of the semiconductor light receiving device 100;

FIG. 3B is a cross sectional view showing a manufacturing process of the semiconductor light receiving device 100;

FIG. 3C is a cross sectional view showing a manufacturing process of the semiconductor light receiving device 100;

FIG. 4 is a cross sectional view showing a semiconductor layer grown on a side wall of a mesa formed along the [01-1] direction in a manufacturing process according to a second example;

FIG. 5 is a cross sectional view showing a structure of a semiconductor light receiving device 200 according to a second exemplary embodiment of the present invention;

FIG. 6 is a top view of the semiconductor light receiving device 200;

FIG. 7A is a cross sectional view showing a manufacturing process of the semiconductor light receiving device according to the second exemplary embodiment;

FIG. 7B is a cross sectional view showing a manufacturing process of the semiconductor light receiving device according to the second exemplary embodiment;

FIG. 7C is a cross sectional view showing a manufacturing process of the semiconductor light receiving device according to the second exemplary embodiment;

FIG. 8 is a cross sectional view showing a structure of a mesa-shaped PIN-PD 80 disclosed in Japanese Unexamined Patent Application Publication No. 2008-66329; and

FIG. 9 is a cross sectional view showing a manufacturing process of the mesa-shaped PIN-PD 80 according to Japanese Unexamined Patent Application Publication No. 2008-66329

### DETAILED DESCRIPTION OF THE EXEMPLARY EMBODIMENTS

Hereinafter, the exemplary embodiments of the present invention will be described with reference to the drawings.

### First Exemplary Embodiment

A semiconductor light receiving device according to a first exemplary embodiment of the present invention will be described. The semiconductor light receiving device according to the present exemplary embodiment is a mesa-shaped PIN-PD formed on a semiconductor substrate. The principal surface of this semiconductor substrate tilts at an angle θ to the (100) plane by using the [01-1] direction as an axis. Further, the angle θ is 0.1 degree≦|θ|≦10 degrees, and independent on the tilting direction.

Here, the range of |θ|≦0.1 degree is eliminated due to the limitations of the manufacturing technology of the semiconductor substrate. Thus, when an attempt is made to manufacture the semiconductor substrate having the (100) plane as a principal surface, the principal surface thereof may tilts to the (100) plane in the range of |θ|≦10 degrees by variability of manufacturing process.

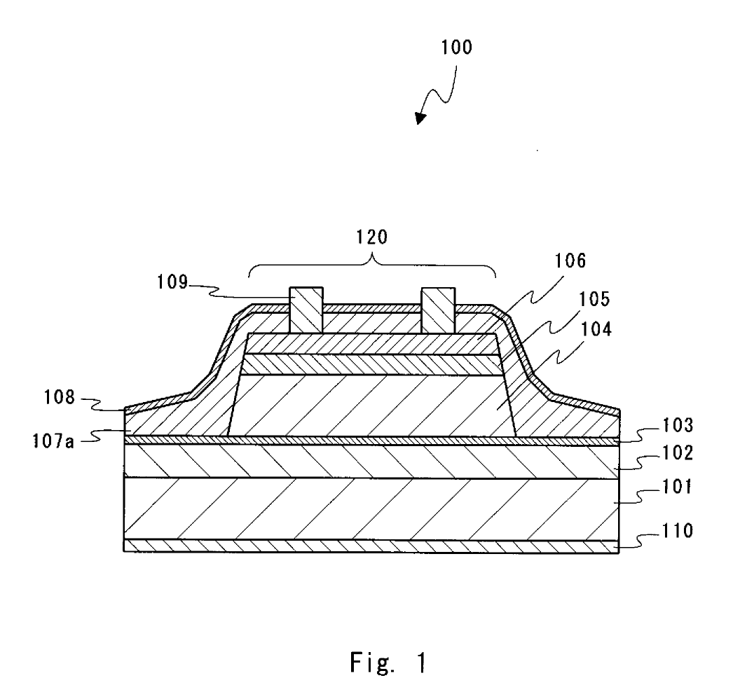

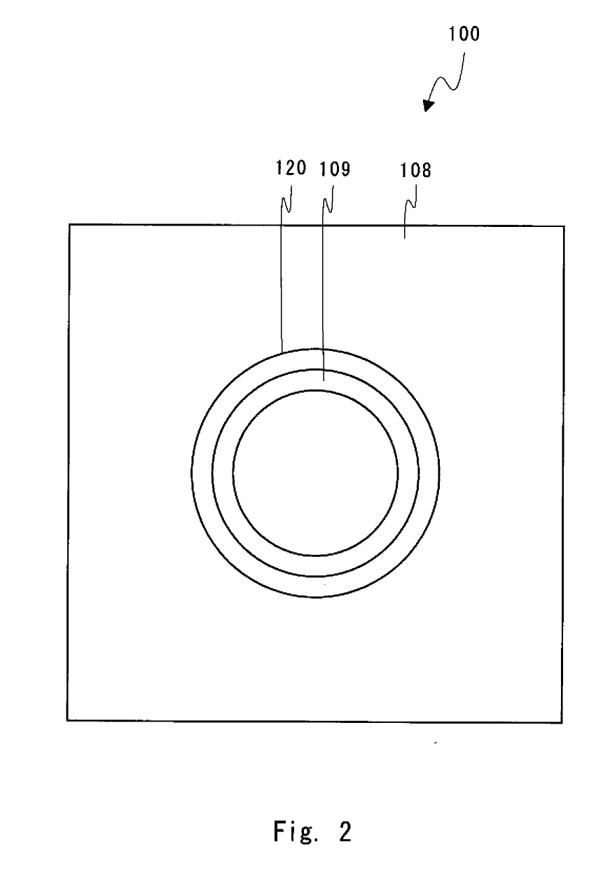

FIG. 1 is a cross sectional view showing a structure of a semiconductor light receiving device 100 according to this exemplary embodiment. Note that FIG. 1 shows a semiconductor mesa formed along the <01-1> direction. FIG. 2 is a top view of the semiconductor light receiving device 100. In the semiconductor light receiving device 100, a buffer layer 102 (a thickness of 1 um) made of n-type InP and an etching stopper layer 103 (a thickness of 20 um to 100 um) made of non-doped InP are grown in this order on a semiconductor substrate 101 made of n-type InP, for example.

A semiconductor mesa 120 is formed on the etching stopper layer 103. The semiconductor mesa 120 includes a light absorption layer 104 (a thickness of 2 um) made of non-doped InGaAs, a cap layer 105 (a thickness of 0.2 um) made of p-type InGaAs, and a contact layer 106 (a thickness of 0.2 um) made of p⁺-type InGaAs formed in this order on the etching stopper layer 103.

Further, a semiconductor layer 107a made of InP covering the semiconductor mesa 120 is formed. A surface protection layer 108 made of silicon nitride is formed on the semiconductor layer 107a, for example. A ring-shaped opening is formed in the semiconductor layer 107a and the surface protection layer 108 on the contact layer 106. A first electrode 109 connecting to the contact layer 106 is formed in the opening. Furthermore, a second electrode 110 is formed on the lower surface of the semiconductor substrate 101.

Referring now to FIG. 2, the semiconductor mesa 120 is formed into a round shape. Further, the first electrode 109 is formed into a ring shape. The surface protection layer 108 covers the entire surface except for an area in which the first electrode 109 is formed.

The semiconductor light receiving device 100 functions as a light receiving device by absorption of the light incidence from above in the light absorption layer 104.

In the structure described above, the compositions and thicknesses of the buffer layer 102, the etching stopper layer 103, the light absorption layer 104, the cap layer 105, and the contact layer 106 are illustrated by way of example. Thus, if it is possible to exert the function as the light receiving device, the compositions and thicknesses of the buffer layer 102, the etching stopper layer 103, the light absorption layer 104, the cap layer 105, and the contact layer 106 can be arbitrarily changed.

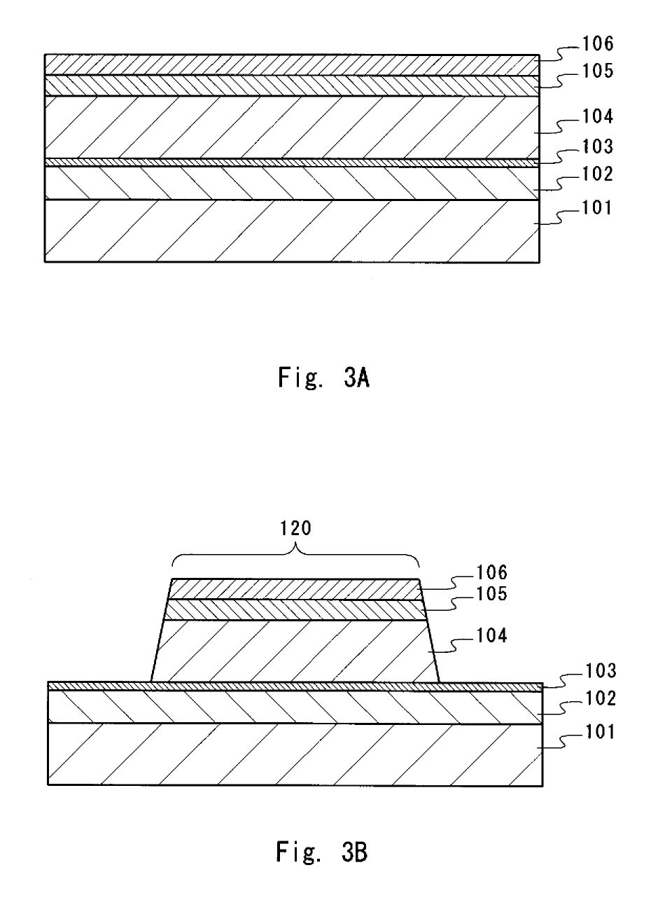

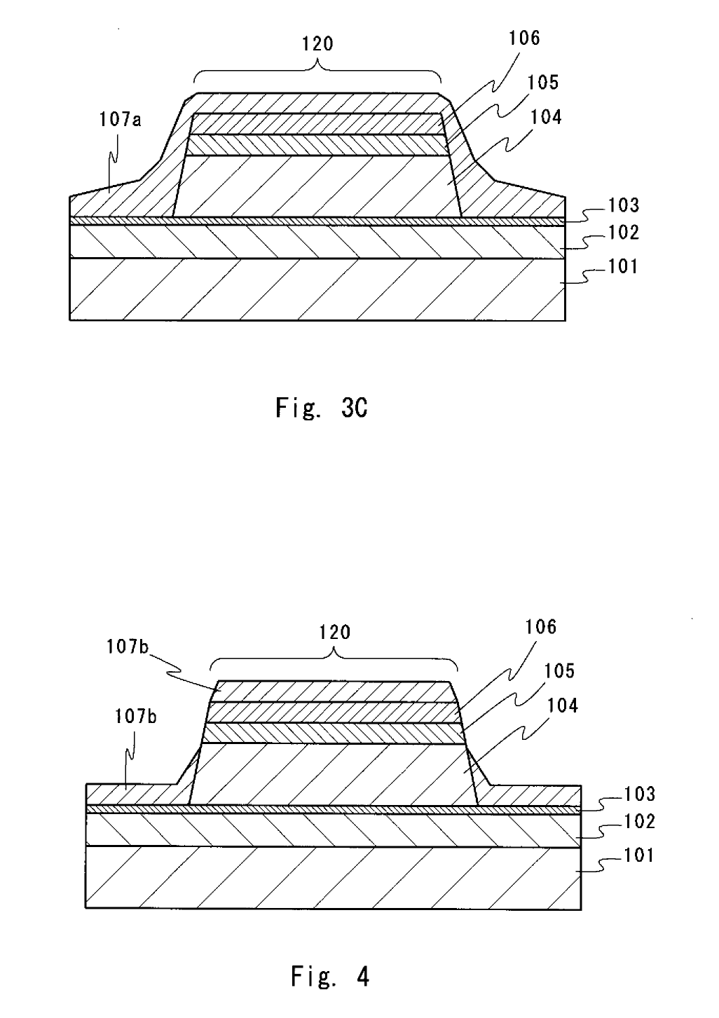

Next, a manufacturing method of the semiconductor light receiving device 100 will be described. FIGS. 3A to 3C are cross sectional views showing the manufacturing method of this semiconductor light receiving device. Firstly, the semiconductor substrate 101 whose tilt angle is 0.1 degree≦|θ|≦10 degrees is prepared. The buffer layer 102, the etching stopper layer 103, the light absorption layer 104, the cap layer 105, and the contact layer 106 are grown in this order on the semiconductor substrate 101 by MOVPE (Metal-Organic Vapor Phase Epitaxy), for example (shown in FIG. 3A).

Next, the circular semiconductor mesa 120 having a diameter of 50 um to 80 um is formed by wet etching, for example (shown in FIG. 3B). In this case, the etching in the depth direction is stopped by the etching stopper layer 103, thereby making it possible to easily control the etching depth.

Next, the semiconductor layer 107a is grown on the side wall of the semiconductor mesa 120 by MOCVD, for example (shown in FIG. 3C). Herein, the principal surface of this semiconductor substrate 101 tilts at the angle θ to the (100) plane by using the [01-1] direction as an axis. Therefore, the step density of the side wall along the [01-1] direction of the semiconductor mesa 120 increases. Thus, generation of a new (111B) plane is prevented, whereby the covering of the side wall of the mesa is promoted. This prevents the light absorption layer 104 from exposing. As a result, the whole side wall around the perimeter of the semiconductor mesa 120 is reliably covered.

Next, the surface protection layer 108 is formed on the semiconductor layer 107a. Subsequently, the ring-shape opening is formed in the semiconductor layer 107a and the surface protection layer 108 on the contact layer 106 by wet etching, for example. After that, the first electrode 109 connecting to the contact layer 106 through this opening is formed. Further, the lower surface of the semiconductor substrate 101 is polished until the thickness of the semiconductor substrate 101 is reduced to about 150 um. Lastly, the second electrode 110 connecting to the lower surface of the semiconductor substrate 101 is formed, and the semiconductor light receiving device 100 shown in FIGS. 1 and 2 is completed.

In sum, according to this structure, even in the case of the semiconductor light receiving device that includes the semiconductor mesa having the side wall along the [01-1] direction, it is possible to reliably cover the side wall of the mesa with the semiconductor layer. Therefore, the exposure of the light absorption layer is prevented, and thus, an increase in the dark current and the decrease in the breakdown voltage can be suppressed. Further, it is possible to manufacture the semiconductor light receiving device 100 by a general manufacturing method. Thus, it is possible to easily obtain the semiconductor light receiving device having the excellent long-term reliability.

Note that the mesa shape is not limited to the round shape. As long as the mesa shape has a side wall formed the [01-1] direction, like an ellipse, for example, it is possible to similarly improve the coverage of the side wall of the mesa.

Further, the larger the value |θ| is, the greater the effect of covering the side wall of the mesa along the [01-1] direction is. However, in the range of |θ|>10 degrees, the shape of the mesa covered with the semiconductor layer is deformed, and optical coupling loss occurs. Thus, this range is impractical. Therefore, it is desirable that the angle θ be 0.1 degree≦|θ|≦10 degrees from a practical point of view.

It is more desirable that the angle θ be 0.1 degree≦|θ|≦2 degrees from a viewpoint of suppressing the deformation of the mesa shape described above.

While the etching stopper layer 103 is formed in the present exemplary embodiment, the etching stopper layer 103 may be omitted if it is possible to form the semiconductor mesa 120 having a desired shape. Further, as long as the PIN structure can be formed, either or both of the buffer layer 102 and the cap layer 105 may be omitted. Therefore, the PIN structure may be formed by forming an intrinsic light absorption layer (corresponding to the light absorption layer 104 in FIG. 1) and a semiconductor layer having a second conductivity type that is opposite to a first conductivity type (corresponding to the contact layer 106 in FIG. 1) on a semiconductor substrate having the first conductivity type (corresponding to the semiconductor substrate 101 in FIG. 1).

### First Example

A first example is directed to a light receiving device in which |θ|=1 degree in the first exemplary embodiment. Since |θ|=1 degree, a favorable mesa shape can be obtained even after the semiconductor mesa formed along the [01-1] direction is covered with the semiconductor layer.

In the semiconductor light receiving device according to the present example, the dark current was suppressed to equal or less than 1 nA at a bias of 5 volts. In addition, GHz-responsiveness was confirmed. Further, the time stability of the dark current was excellent. For example, the dark current did not increase after aging for 1000 hours at 140 degrees Celsius. This made it possible to confirm that the semiconductor light receiving device according to the present example had the excellent reliability.

Note that, as described in the first exemplary embodiment, the plane direction of the semiconductor substrate varies due to the limitations of the manufacturing technology of the semiconductor substrate. Therefore, the plane direction of the semiconductor substrate 101 in the present example had a range of 0.9 degree≦|θ|≦1.1 degrees.

### Second Example

A second example is directing to a light receiving device in which the principal surface of the semiconductor substrate 101 is intentionally set as a (100) just plane. Note that the (100) just plane may have a tilt angle of |θ|<0.1 degree due to the limitations of the manufacturing technology of the semiconductor substrate as described in the first exemplary embodiment. FIG. 4 is a cross sectional view showing a semiconductor layer grown on a side wall of a mesa formed along the [01-1] direction in a manufacturing process according to the present example. In the present example, as shown in FIG. 4, a semiconductor layer 107b could not cover the whole side wall around the perimeter of the semiconductor mesa 120, and the light absorption layer 104 was partly exposed. Therefore, it was confirmed that the reliability of the light receiving device cannot be ensured in the case where the principal surface of the semiconductor substrate 101 was set as the (100) just plane.

### Second Exemplary Embodiment

A semiconductor light receiving device according to a second exemplary embodiment of the present invention will be described. The semiconductor light receiving device according to the present exemplary embodiment is a mesa-shaped APD formed on a semiconductor substrate. The principal surface of this semiconductor substrate tilts at the angle θ to the (100) plane by using the [01-1] direction as an axis, like the first exemplary embodiment.

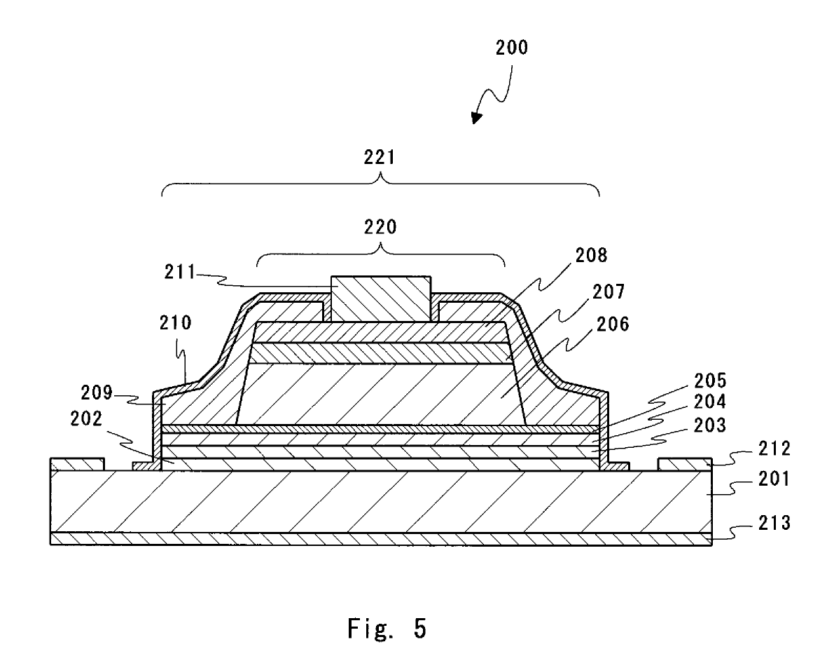

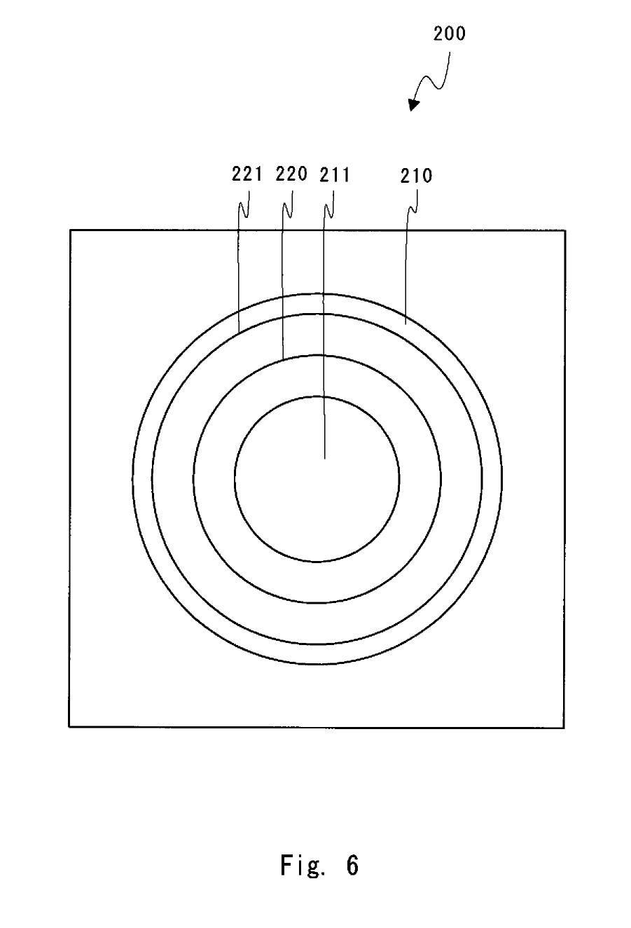

FIG. 5 is a cross sectional view showing a structure of a semiconductor light receiving device 200 according to the present exemplary embodiment. Besides, FIG. 5 shows a semiconductor mesa formed along the <01-1> direction. FIG. 6 is a top view of the semiconductor light receiving device 200. In the semiconductor light receiving device 200, a buffer layer 202 (a thickness of 1 um) made of n-type InP, an intensification layer 203 (a thickness of 0.2 um to 0.3 um) made of non-doped InAlAs, an electric field relaxation layer 204 (a thickness of 20 um to 100 um) made of p-typed InAlAs, and an etching stopper layer 205 (a thickness of 20 um to 100 um) made of p-type InP are grown in this order on a semiconductor substrate 201 made of n-type InP, for example.

A semiconductor mesa 220 is formed on the etching stopper layer 205. The semiconductor mesa 220 includes a light absorption layer 206 (a thickness of 0.5 um to 2 um) made of p-type InGaAs, a cap layer 207 (a thickness of 0.2 um) made of p-type InGaAs, and a contact layer 208 (a thickness of 0.2 um) made of p⁺-type InGaAs formed in this order on the etching stopper layer 205.

Further, a semiconductor layer 209 made of InP covering the semiconductor mesa 220 is formed, for example. A surface protection layer 210 made of silicon nitride is formed on the semiconductor layer 209, for example. A circular opening is formed in the semiconductor layer 209 and the surface protection layer 210 on the contact layer 208. A first electrode 211 connecting to the contact layer 208 is formed in the opening. A second electrode 212 is formed on the upper surface of the semiconductor substrate 201. Further, an anti-reflection layer 213 is formed on the lower surface of the semiconductor substrate 201.

The semiconductor light receiving device 200 functions as a light receiving device by absorption of the light incidence from below in the light absorption layer 206.

In the structure described above, the compositions and thicknesses of the buffer layer 202, the intensification layer 203, the electric field relaxation layer 204, the etching stopper layer 205, the light absorption layer 206, the cap layer 207, and the contact layer 208 are illustrated by way of example. Thus, if it is possible to exert the functions as the light receiving device, the compositions and thicknesses of the buffer layer 202, the intensification layer 203, the electric field relaxation layer 204, the etching stopper layer 205, the light absorption layer 206, the cap layer 207, and the contact layer 208 can be arbitrarily changed.

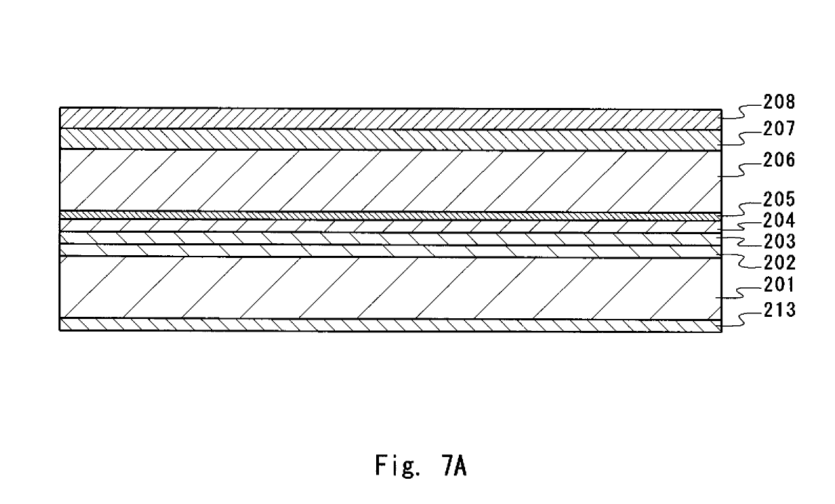

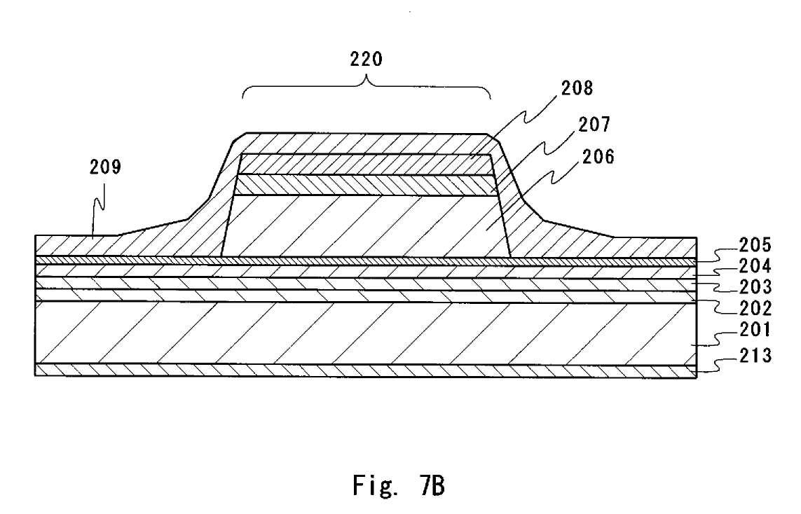

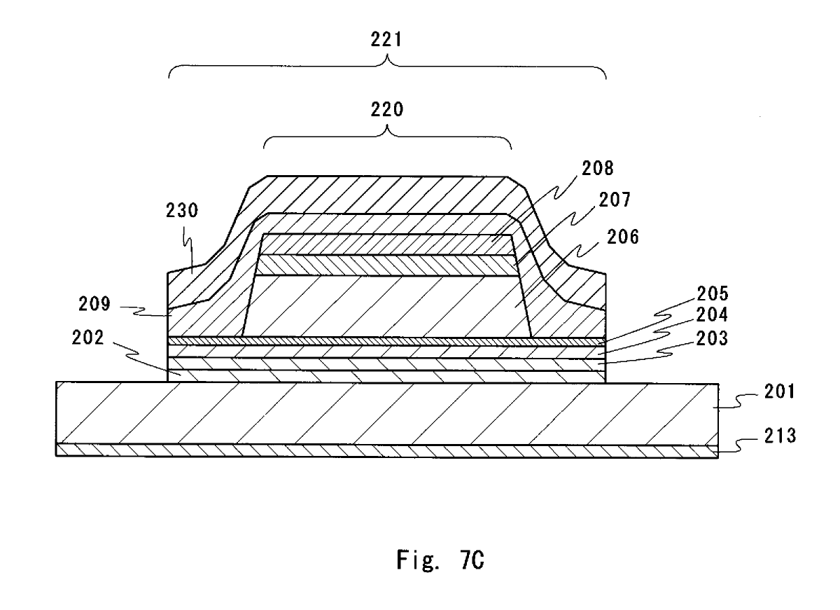

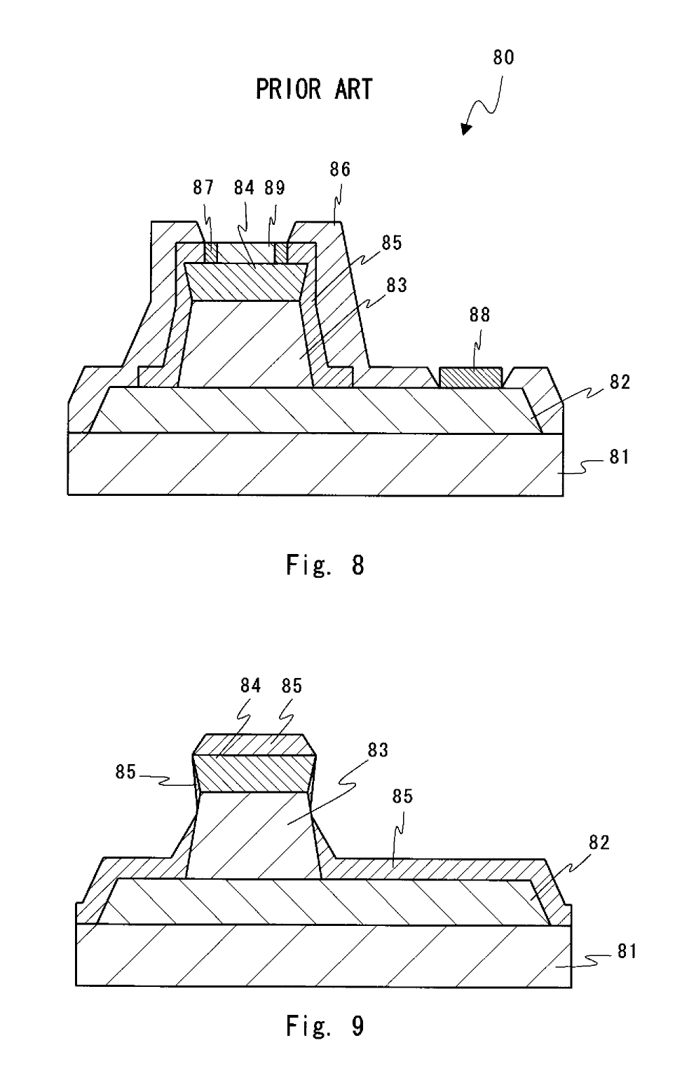

Next, a manufacturing method of the semiconductor light receiving device 200 will be described. FIGS. 7A to 7C are cross sectional views showing the manufacturing method of this semiconductor light receiving device. Firstly, the semiconductor substrate 201 whose tilt angle is 0.1 degree≦|θ|≦10 degrees as described above is prepared. The buffer layer 202, the intensification layer 203, the electric field relaxation layer 204, the etching stopper layer 205, the light absorption layer 206, the cap layer 207, and the contact layer 208 are grown in this order on the semiconductor substrate 201 by MBE (Molecular Beam Epitaxy), for example (shown in FIG. 7A).

Next, the circular semiconductor mesa 220 having a diameter of 30 um to 50 um is formed by wet etching, for example. In this case, the etching in the depth direction stopped by the etching stopper layer 205, thereby making it possible to easily control the etching depth. Subsequently, the semiconductor layer 209 is grown on the side wall of the semiconductor mesa 220 by MOVPE, for example (shown in FIG. 7B). Herein, the principal surface of the semiconductor substrate 201 tilts at the angle θ to the (100) plane by using the [01-1] direction as an axis. Therefore, the step density of the side wall along the [01-1] direction of the semiconductor mesa 220 increases. Thus, generation of a new (111B) plane is prevented, whereby the covering the side wall of the mesa is promoted. This prevents the light absorption layer 206 from exposing. As a result, the whole side wall around the perimeter of the semiconductor mesa 220 is reliably covered.

Further, a mask 203 which has a diameter of 35 um to 55 um and is concentric to the semiconductor mesa 220 is formed. A mask 230 can be formed of insulating film such as a silicon oxide film, a silicon nitride film, or photoresist. The semiconductor layer 209, the etching stopper layer 205, the electric field relaxation layer 204, the intensification layer 203, the buffer layer 202 are removed by etching using the mask 230 as an etching mask, thereby forming a semiconductor mesa 221 (shown in FIG. 7C).

After that, the surface protection layer 210, the first electrode 211, and the second electrode 212 are formed. Further, the lower surface of the semiconductor substrate 201 is polished until the thickness of the semiconductor substrate 201 is reduced to about 150 um. Lastly, the anti reflection layer 213 is formed, and the semiconductor light receiving device 200 is completed.

In sum, according to this structure, even in the case of the semiconductor light receiving device that includes the semiconductor mesa having the side wall along the [01-1] direction, it is possible to reliably cover the side wall of the mesa with the semiconductor layer. Therefore, like the first exemplary embodiment, the exposure of the light absorption layer is prevented, thus, an increase in the dark current and a decrease in the breakdown voltage can be suppressed. Further, it is possible to manufacture the semiconductor light receiving device 200 by a general manufacturing method. Thus, it is possible to easily obtain the semiconductor light receiving device having the excellent long-term reliability.

### Third Example

A third example is directed to the light receiving device 200 in which |θ|=1 degree in the second exemplary embodiment. Since |θ|=1 degree, a favorable mesa shape can be obtained even after the semiconductor mesa formed along [01-1] direction is covered with the semiconductor layer.

In the light receiving device 200 according to the present example, a breakdown voltage Vbr (which was defined when the current was 10 um) could be suppressed to 20 V to 45 V. Further, the dark current could be suppressed to equal to or less than 40 nA at a bias of 0.9 Vbr in the semiconductor light receiving device 200. Furthermore, the GHz responsiveness was confirmed in the light receiving device 200. In addition, the light receiving device 200 had excellent time stability of the dark current. For example, the dark current did not increase after aging for 5000 hours at 150 degrees Celsius. Therefore, it was confirmed that the light receiving device 200 according to the present example had the excellent reliability.

Note that, as described in the first exemplary embodiment, the plane direction of the semiconductor substrate varies due to the limitations of the manufacturing technology of the semiconductor substrate. Therefore, the plane direction of the semiconductor substrate 101 in the present example had a range of 0.9 degree≦|θ|≦1.1 degrees.

While the etching stopper layer 205 is formed in the present exemplary embodiment, the etching stopper layer 205 may be omitted if it is possible to form the semiconductor mesa 220 having a desired shape. Furthermore, as long as the avalanche photodiode can be formed, either or both of the buffer layer 202 and the cap layer 207 may be omitted.

### Other Exemplary Embodiments

The present invention is not limited to the exemplary embodiments described above, but can be changed as appropriate without departing from the spirit of the present invention. For example, the semiconductor layer 107a shown in FIG. 1 and the semiconductor layer 209 shown in the FIG. 5 are not limited to ones made of non-doped InP. For example, if the semiconductor layer 107a and the semiconductor layer 209 are made of P-type or n-type InP having an impurity concentration equal to or less than 5·10¹⁶ cm⁻³, it is possible to obtain the semiconductor light receiving device having the same performance and effect. Further, the semiconductor light receiving device having the same performance and effect can be obtained also when the semiconductor layer 107a and the semiconductor layer 209 are made of semi-insulating InP.

The n and p conductivity types can be exchanged in the semiconductor light receiving devices 100 and 200.

The second electrode 110 in the semiconductor light receiving device 100 may be formed in an area on the top surface of the semiconductor substrate 101 in which the semiconductor mesa 120 is not formed.

The first and second exemplary embodiments can be combined as desirable by one of ordinary skill in the art.

While the invention has been described in terms of several exemplary embodiments, those skilled in the art will recognize that the invention can be practiced with various modifications within the spirit and scope of the appended claims and the invention is not limited to the examples described above.

Further, the scope of the claims is not limited by the exemplary embodiments described above.

Furthermore, it is noted that, Applicant's intent is to encompass equivalents of all claim devices, even if amended later during prosecution.

What is claimed is:

1. a semiconductor light receiving device comprising:
a semiconductor substrate having a first conductivity type;
a semiconductor mesa arranged over the semiconductor substrate; and
a first semiconductor layer covering at least a side wall of the semiconductor mesa, wherein
the semiconductor mesa comprises:
a light absorption layer; and
a second semiconductor layer that is arranged over the light absorption layer and has a second conductivity type opposite to the first conductivity type,
the principal surface of the semiconductor substrate tilts at an angle θ to a (100) plane by using [01-1] direction as an axis, and
the angle θ is 0.1 degree≦|θ|≦10 degrees.

2. The semiconductor light receiving device according to claim 1, wherein the angle θ is 0.1 degree≦|θ|≦2 degrees.

3. The semiconductor light receiving device according to claim 1, wherein the angle |θ| substantially equals 1 degree.

4. The semiconductor light receiving device according to claim 1, wherein
the light absorption layer is made of intrinsic semiconductor, and
the semiconductor light receiving device is a PIN photodiode.

5. The semiconductor light receiving device according to claim 1, wherein
the light absorption layer is made of semiconductor having the first type conductivity or the second type conductivity, and
the semiconductor light receiving device is an avalanche photodiode.
